(19) United States
(12) Patent Application Publication
(10) Pub. No.: US 2021/0364840 A1
(43) Pub. Date: Nov. 25, 2021

(54) PHOTOMASK FOR FABRICATING PADDED BLACK PHOTO SPACER AND LIQUID CRYSTAL DISPLAY PANEL

(71) Applicant: Shenzhen China Star Optoelectronics Technology Co., Ltd., Shenzhen (CN)

(72) Inventor: Wu Cao, Shenzhen (CN)

(21) Appl. No.: 16/319,467

(22) PCT Filed: Nov. 22, 2018
(86) PCT No.: PCT/CN2018/116937

§ 371 Date: Jan. 21, 2019

(30) Foreign Application Priority Data
Sep. 26, 2018 (CN) 201811126276.9

(51) Int. Cl. G02F 1/1339; G02F 1/1335; G03F 1/32

(52) U.S. Cl. CPC G02F 1/13394; G02F 1/133514; G02F 1/1368; G02F 1/133512; G03F 1/32; G02F 1/13396

(57) ABSTRACT

Provided are a photomask for fabricating a padded black photo spacer and a liquid crystal display panel. The photomask is provided with a pad pattern for forming a main photo spacer color resist pad, wherein the pad pattern includes a light transmissive region and a light shielding pattern having a critical dimension disposed in the light transmissive region; the light shielding pattern having the critical dimension is a regular pattern having a sufficiently small line dimension in a certain characteristic direction; the critical dimension is less than or equal to 5 μm. The photomask can increase a level difference conversion rate when black photo spacer material is subsequently coated, and finally, the actual level difference between the main photo spacer and the auxiliary photo spacer can be adjusted upward; the padded black photo spacer of the liquid crystal display panel possesses a larger level difference.

### FIELD OF THE INVENTION

The present invention relates to a display technology field, and more particularly to a photomask for fabricating a padded black photo spacer and a liquid crystal display panel.

### BACKGROUND OF THE INVENTION

The LCD (Liquid Crystal Display) panel possesses many advantages of being ultra thin, power saved and radiation free. It has been widely utilized in, such as LCDTV, smart phones, digital cameras, tablets, laptop screens or notebook screens, and dominates the flat panel display field.

The BPS (Black Photo Spacer) technology integrates two separate processes of a black matrix (BM) and a photo spacer (PS) in a conventional LCD into one process, and uses black shading photosensitive resin to form three functional structures of different heights. These are the main photo spacer (Main PS)/sub photo spacer (Sub PS) and the black matrix from high to low for forming a variety of level differences. FIG. 1 and FIG. 2 show two main structural designs of black photo spacer (BPS) technology in the prior art. Unlike the separation architecture of black matrix and spacer in the prior art, in the BPS technology a black matrix and photo spacers are formed by the same material with one exposure process. The color resist can form a pad that becomes a part of the photo spacer; the level difference between the main photo spacer and the auxiliary photo spacer is formed by the difference in the thickness of the pad or the film thickness of the BPS layer.

The first structural design of BPS technology in the prior art is shown in FIG. 1. The surface of the substrate 1 on which the BPS layer is located is flat, and after coating the BPS materials having different transmittances, the main photo spacer 2, the auxiliary photo spacer 3 and the black matrix 4, which have heights of H1, H2 and H3, are formed by one exposure process by using a halftone mask (HTM), thereby forming a level difference between the main photo spacer 2 and the auxiliary photo spacer 3; the second structural design of BPS technology in the prior art is shown in FIG. 2. The main photo spacer and the auxiliary photo spacer are respectively formed by the structures of the color resist pads 16, 16′ and the thin film transistors 11, 11′. The main photo spacer pad and the auxiliary photo spacer pad constitute a pad step, such that the BPS layer composed of the main photo spacer 13, the auxiliary photo spacer 14 and the black matrix 15 possesses various heights on the surface of the lower glass substrate 10, and the color resist pads 16, 16′ may be composed of one or more layers of color resists (a layer of blue (B) color resist in FIG. 2), and the color resist pads 16, 16′ are covered with an inorganic passivation layer 12, and finally, a single transmittance BPS material is coated and a full-tone mask (FTM) is used in an exposure process to form the main photo spacer 13, the auxiliary photo spacer 14 and the black matrix 15 with level differences with one another. Then, the upper glass substrate 20 and the transparent electrode 21 are further provided above.

Comparing the first structural design with the second structural design, the second structural design with less requirement for BPS material and photomask is relatively more promising; in the second structural design, after the RGB color resist is formed, the inorganic passivation layer, such as SiNx covers thereon. In BPS technology for forming a pad step on the lower substrate by using a single layer of color resist (the film formation height of the color resist pad under the auxiliary photo spacer is reduced by a process, such as a halftone mask (HTM)/a grey mask (GTM)), the level difference is generally small, and is affected by the process exposure amount and the underlying pad material.

In some applications, the smaller level difference is easy to cause the LC Margin window to be small, and the fault tolerance is low, and the process risk such as vacuum bubbles may easily occur.

FIG. 3 shows a top view diagram of a color resist pad. Except the RGB color resist 30, after the color resist at the thin film transistor 31 forms the island shaped color resist pad 32 with the FTM process and the island shaped color resist pad 33 with the GTM process, the pad step having level difference is formed. The color resist pad 32 and the color resist pad 33 can serve as color resist pads for the main photo spacer and the auxiliary photo spacer, respectively. Then the BPS material is coated, and is exposed and developed after leveling to form a long stripe type BPS patter to obtain a final photo spacer structure.

Experiments have shown that when the pad is disposed on a metal pattern such as a thin film transistor, the amount of reflected light received by the auxiliary photo spacer pad formed by the GTM process is increased, resulting in a reduction in the level difference of the final pad step. The level difference after forming the color resist pad is highly correlated with the process conditions, and the process fluctuation has a great influence; even if the auxiliary photo spacer is moved to the storage capacitor region, there is still metal reflection, and the effect of increasing the level difference is limited; and moreover, the difference in the placement of the main photo spacer and the auxiliary photo spacer will not introduce inconvenience to the discussion of the photo spacer ratio (PS Ratio).

FIG. 4 is a comparison diagram of a surface flatness of a color resist pad in the prior art. The left side is the main photo spacer color resist pad 401, and the right side is the auxiliary photo spacer color resist pad 402. The photomask of the main photo spacer color resist pad 401 adopts a full transparent opening design, and the corresponding photomask of the auxiliary photo spacer color resist pad 402 adopts a slit (Silt) design. A clear flatness difference can be seen after forming the color resist pad. The main photo spacer color resist pad 401 planarizes the lower thin film transistor ground, and the auxiliary photo spacer color resist pad 402 is not flat due to the slit itself and the electrode bump of the thin film transistor. FIG. 5 is a comparison diagram of surface flatnesses of a main photo spacer and an auxiliary photo spacer in the prior art. The left side is a front view, a top view and a right view of the main photo spacer 501, and the right side is a front view, a top view and a right view of the auxiliary photo spacer 502. After the BPS film is formed on the color resist pad shown in FIG. 4, the main photo spacer 501 is still flat, and the roughness of the auxiliary photo spacer 502 is flattened to some extent, but there is still undulation. In the prior art, due to metal reflection, the thickness of the auxiliary photo spacer color resist pad 402 is larger than expected, resulting in a smaller final level difference, which affects the field of liquid crystal.

### SUMMARY OF THE INVENTION

An objective of the present invention is to provide a photomask for fabricating a padded black photo spacer, which increases a level difference conversion rate when black photo spacer material is subsequently coated.

Another objective of the present invention is to provide a liquid crystal display panel, in which the padded black photo spacer possesses a larger level difference.

For realizing the aforesaid objectives, the present invention provides a photomask for fabricating a padded black photo spacer, provided with a pad pattern for forming a main photo spacer color resist pad, wherein the pad pattern includes a light transmissive region and a light shielding pattern having a critical dimension disposed in the light transmissive region; the light shielding pattern having the critical dimension is a regular pattern having a sufficiently small line dimension in a certain characteristic direction; the critical dimension is less than or equal to 5 μm.

A transmissive area proportion of the pad pattern is larger than or equal to 70%.

The light shielding pattern is a square shape, a triangular shape, a circular shape, an array of square shapes, a line shape, a mesh shape or a homocentric squares shape.

The critical dimension is less than or equal to 2 μm.

The light shielding pattern is a single pattern, or a one-dimensional or two-dimensional array arrangement of a single pattern.

The light-shielding pattern is a complete light-shielding pattern having a transmittance of 0% or a light-shielding pattern having a reduced transmittance.

The present invention further provides a liquid crystal panel, including an upper substrate, a lower substrate and a padded black photo spacer disposed on the lower substrate; wherein the padded black photo spacer includes a photo spacer and a photo spacer pad disposed on the lower substrate and corresponding to the photo spacer, and a surface of the color resist layer in the photo spacer pad is provided with micro pits.

The padded black photo spacer includes a main photo spacer, an auxiliary photo spacer, a black matrix, a main photo spacer pad and an auxiliary photo spacer pad; the main photo spacer pad and the auxiliary photo spacer pad are disposed on the lower substrate, and a height of the main photo spacer pad is greater than a height of the auxiliary photo spacer pad; the black matrix and the main photo spacer are correspondingly disposed above the main photo spacer pad, and the black matrix and the auxiliary photo spacer are correspondingly disposed above the auxiliary photo spacer pad; the main photo spacer pad includes a main photo spacer color resist pad, and a surface of the main photo spacer color resist pad is provided with micro pits.

The micro pits are grooved or concaved and convexed in a lattice shape, and are located on the color resist layer near the surface of the photo spacer and possess a local roughness greater than 0.1 μm and less than 0.3 μm.

A groove structure with a high circumference and a slightly depressed central portion is formed on a top of the photo spacer, and the groove structure possesses a peak and trough value greater than 0.1 μm and less than 0.5 μm.

The color resist layer in the photo spacer pad forms the photo spacer color resist pad, and the photo spacer color resist pad includes one or more layers of color resists.

The photo spacer pad further includes an inorganic planarization layer or an organic planarization layer, or includes a thin film transistor.

In conclusion, the photomask for fabricating the padded black photo spacer can increase a level difference conversion rate when black photo spacer material is subsequently coated, and finally, the actual level difference between the main photo spacer and the auxiliary photo spacer can be adjusted upward; the padded black photo spacer of the liquid crystal display panel possesses a larger level difference.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram of a first structural design of black photo spacer (BPS) technology in the prior art;

FIG. 2 is a diagram of a second structural design of black photo spacer (BPS) technology in the prior art;

FIG. 3 is a top view diagram of a color resist pad;

FIG. 4 is a comparison diagram of a surface flatness of a color resist pad in the prior art;

FIG. 5 is a comparison diagram of surface flatnesses of a main photo spacer and an auxiliary photo spacer in the prior art;

FIG. 6A is a top view diagram of a photomask for fabricating a padded black photo spacer in the prior art, and FIG. 6B is a top view diagram of a color resist pattern formed by applying the photomask shown in FIG. 6A, and FIG. 6C is a cross-sectional diagram of a main photo spacer color resist pad formed by applying the photomask shown in FIG. 6A;

FIG. 6D is a top view diagram of a preferred embodiment of a photomask for fabricating a padded black photo spacer, and FIG. 6E is a top view diagram of a color resist pattern formed by using the photomask shown in FIG. 6D, and FIG. 6F is a cross-sectional diagram of a main photo spacer color resist pad formed by applying the photomask shown in FIG. 6D;

FIG. 7 is a principle diagram of a photomask for fabricating a padded black photo spacer according to the present invention;

FIG. 8 is a diagram of a light shielding pattern having a critical dimension of a photomask for fabricating a padded black photo spacer according to the present invention;

FIG. 9 is a structural diagram of a liquid crystal display panel according to a preferred embodiment of the present invention.

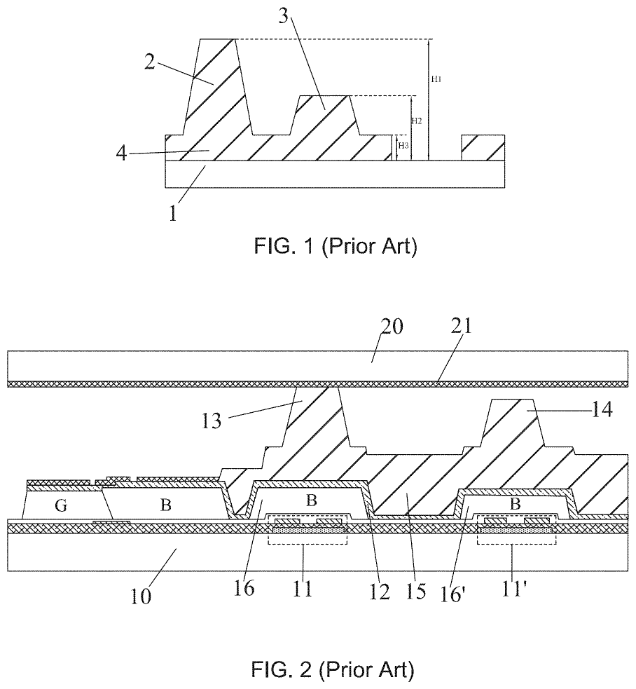

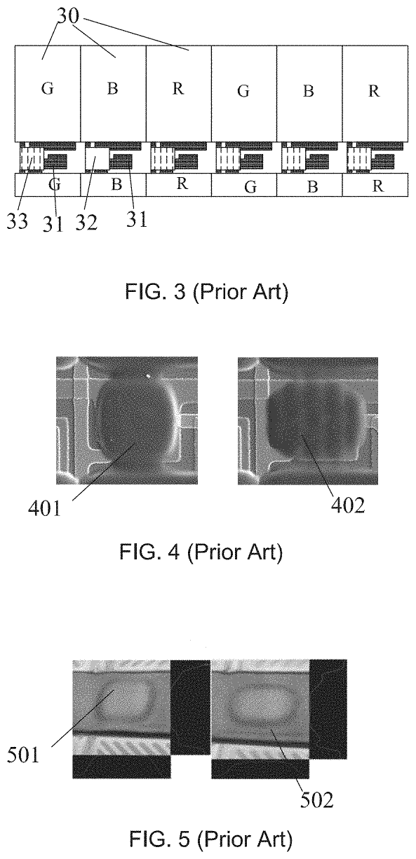

### DETAILED DESCRIPTION OF PREFERRED EMBODIMENTS

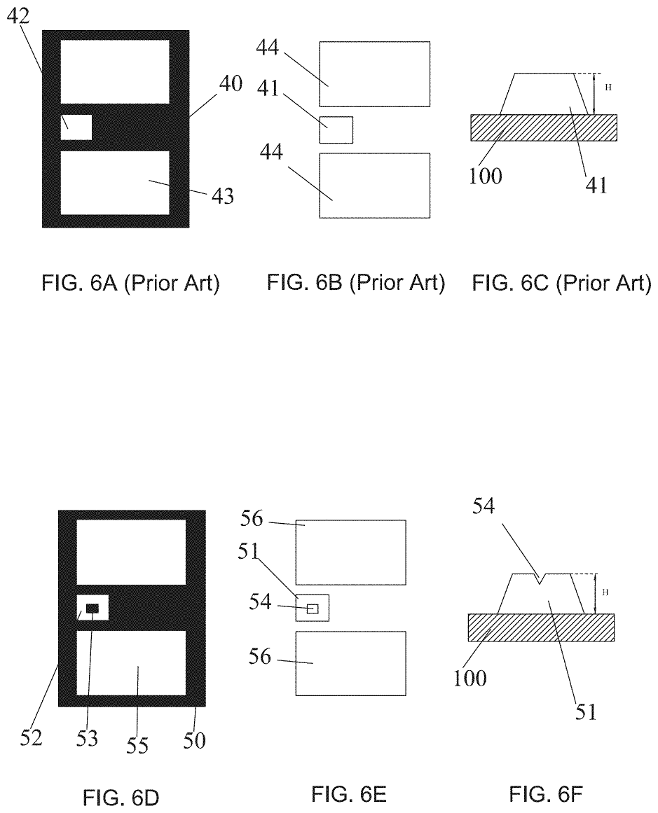

FIG. 6A is a top view diagram of a photomask 40 for fabricating a padded black photo spacer in the prior art, and FIG. 6B is a top view diagram of a color resist pattern formed by applying the photomask 40, and FIG. 6C is a cross-sectional diagram of a main photo spacer color resist pad 41 formed by applying the photomask 40. The photomask 40 is provided with a pad pattern 42 for forming a main photo spacer color resist pad 41, and the pad pattern 42 is a large opening transmissive region; the photomask 40 further includes a RGB color resist pattern 43 for forming RGB color resists 44, and the RGB color resist pattern 43 is a large opening transmissive region. The RGB color resist pattern 43 and the pad pattern 42 of the prior art are designed to be transparent to the whole. Namely, the light transmittance T is equal to 100%, and a height of the main photo spacer color resist pad 41 formed on the substrate 100 is H.

FIG. 6D is a top view diagram of a preferred embodiment of a photomask 50 for fabricating a padded black photo spacer, and FIG. 6E is a top view diagram of a color resist pattern formed by using the photomask 50, and FIG. 6F is a cross-sectional diagram of a main photo spacer color resist pad 51 formed by applying the photomask 50. The photomask 50 of the present invention can be made on the basis of the photomask 40 shown in FIG. 6A. The photomask 50 of the present invention includes a pad pattern 52 for forming a main photo spacer color resist pad 51, and the pad pattern 52 mainly includes a large opening transmissive region, and the pad pattern 52 further includes a light shielding pattern 53 having a critical dimension (CD) for forming a small range of pits 54 on an upper surface of the main photo spacer color resist pad 51, and the light shielding pattern 53 is disposed in a transmissive region of the pad pattern 52. In the present application, the critical dimension refers to the designed size, and the light shielding pattern having the critical dimension is a regular pattern having a sufficiently small line dimension in a certain characteristic direction. The photomask 50 further includes an RGB color resist pattern 55 for forming an RGB color resist 56, and the RGB color resist pattern 55 is a large opening transmissive region.

In the present invention, the light shielding pattern 53 having a critical dimension is disposed in the large opening transmissive region of the pad pattern 52 to ensure that the transmissive area proportion of the pad pattern 52 is not less than 70%. Namely, the ratio of the transmissive area to the entire pad pattern 52 is not less than 70%, and it is prevented that the light shielding stripe is excessive, and the light transmittance is seriously lowered, and the film forming height is lowered.

In the present invention, the light transmittance is reduced in a small area of the pad pattern 52 by using the light shielding pattern 53 to increase a surface roughness of the main photo spacer color resist pad 51, and the height H of the main photo spacer color resist pad 51 formed on the substrate 100 is hardly reduced. The light shielding pattern 53 formed of a Cr metal film having a light transmittance of 0% is illustrated. Since the light shielding pattern 53 is configured to have the critical dimension, which is generally not more than 5 μm, and the total area of the light shielding pattern 53 may be less than 30% of the total opening area of the pad pattern 52.

The present invention specifically designs the pad pattern for forming main photo spacer color resist pad in the photomask, including the light shielding pattern having the critical dimension (the color resist is generally a negative material to be exposed for film formation), such as dots/lines (Dot/Line), and the surface roughness of the main photo spacer color resist pad is increased without lowering the overall height (most or the highest point). In the present invention, the auxiliary photo spacer color resist pad can be kept unchanged from the original design, or the position can be changed.

The photomask of the present invention is used to form the main photo spacer color resist pad having a rough upper surface, and the light shielding pattern having the critical dimension increases the surface roughness of the main photo spacer color resist pad, but the overall height of the main photo spacer color resist pad is not changed. Since the BPS material coated thereafter is palanarized, the remaining thickness of the BPS material on the main photo spacer color resist pad can be improved, i.e. the height of the main photo spacer can be increased to correspondingly increase the level difference of the photo spacers, which is advantageous for the process range.

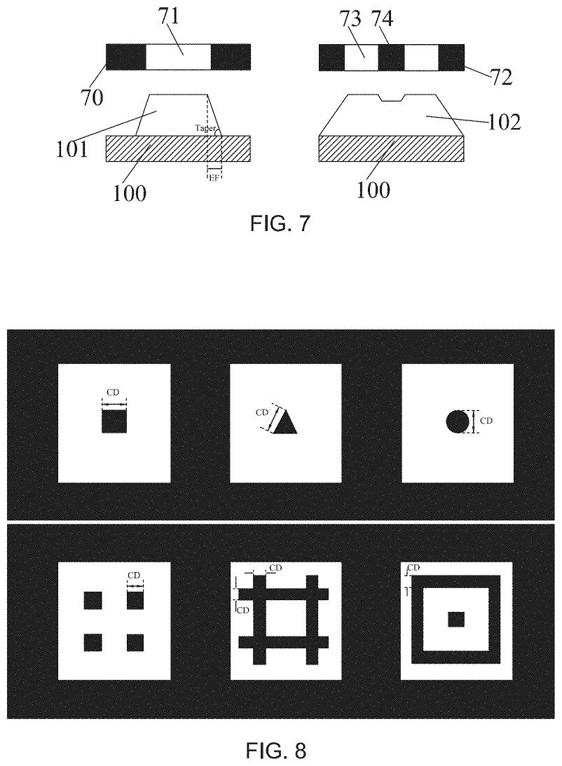

FIG. 7 is a principle diagram of a photomask for fabricating a padded black photo spacer according to the present invention; the left side of FIG. 7 shows the organic photoresist 101 on the substrate 100 exposed under the general photomask 70, and the photomask 70 is provided with a light transmissive region 71; the right side of FIG. 7 shows the organic photoresist 102 on the substrate 100 exposed under the photomask 72 of the present invention. The photomask 72 is provided with a light transmissive region 73. A light shielding pattern 74 having a critical dimension is added in the light transmissive region 73. The basic principles utilized by the present invention are: the organic photoresist (color resist) is patterned during exposure by receiving light energy transmitted through the transparent region of the photomask but the actual pattern of the organic photoresist is sloped. In the present invention, as patterning the organic photoresist, the projection distance of the pattern boundary slope in the horizontal plane is represented by EF, and the projection distance is represented by the EF value; the smaller the EF value, the steeper the pattern boundary is and the larger the taper angle is; the EF value corresponds to the film thickness thinning zone of the pattern boundary, and the film thickness thinning zone can form a certain thickness film by superimposing and leveling with each other, and the degree depends on the material property and the process conditions.

When the critical dimension and area ratio of the light shielding pattern of the pad pattern for forming the main photo spacer color resist pad in the photomask meets the requirements of the present technical solution, the surface roughness of the main photo spacer color resist pad can be increased without reducing the film thickness; the pad design of using the main photo spacer color resist pad with the rough surface under the main photo spacer can increase the final level difference conversion rate or the photo spacer level difference.

The present invention is directed to a BPS technology architecture using underlying pads, particularly for color resist pads formed by organic photoresist. The light shielding pattern having the critical dimension (a regular pattern having critical dimension not more than 5 μm in some dimension and the total shielding area is less than 30%) is introduced on the photomask. By using the overlay of the organic film thickness thinning zones, the upper surface roughness of the color resist pad can be increased without substantially reducing the overall film thickness. The level difference conversion rate (photo spacer level difference/pad level difference) can be increased when black photo spacer material is subsequently coated, and finally, the actual level difference between the main photo spacer and the auxiliary photo spacer can be adjusted to increase. By using the photomask of the present invention, the organic material in the process can be fully utilized, and the utilization rate is high; the existing process can be shortened.

Please refer to FIG. 8, which is a diagram of a light shielding pattern having a critical dimension of a photomask for fabricating a padded black photo spacer according to the present invention. The pad pattern for forming the main photo spacer color resist pad in the photomask mainly includes a large opening transmissive region, and further includes the light shielding pattern having the critical dimension for forming a small range of pits on the upper surface of the main photo spacer color resist pad. The light shielding pattern having the critical dimension refers to a regular pattern having a sufficiently small line dimension in a certain characteristic direction. As shown in FIG. 8, the light shielding pattern may be a square shape, a triangular shape, a circular shape, an array of square shapes, a line shape, a mesh shape or a homocentric squares shape in the light transmissive region; the critical dimension is not more than 5 μm, and the better, the critical dimension is no more than 2 μm. The critical dimension refers to the smallest axial critical dimension in the light shielding pattern, that is, when the two critical dimensions in two dimensions are inconsistent, whichever is the smallest; for the irregular light shielding patterns, such as triangles and circles, the critical dimensions respectively are side length and diameter; in FIG. 8, the specific critical dimensions of the respective light shielding patterns are indicated by the term CD. The light shielding pattern having the critical dimension may be a single designed pattern, or a one-dimensional or two-dimensional array arrangement of a single pattern. The light shielding pattern having the critical dimension which can be used in the present invention includes, but is not limited to, the patterns shown in FIG. 8. In addition to the patterns shown in FIG. 8, the shape may also be a line shape or the like, and the light shielding pattern having the critical dimension. In addition to the complete light shielding pattern having a transmittance of 0%, the light shielding pattern having the critical dimension in the present invention may also be a design for reducing transmittance such as HTM.

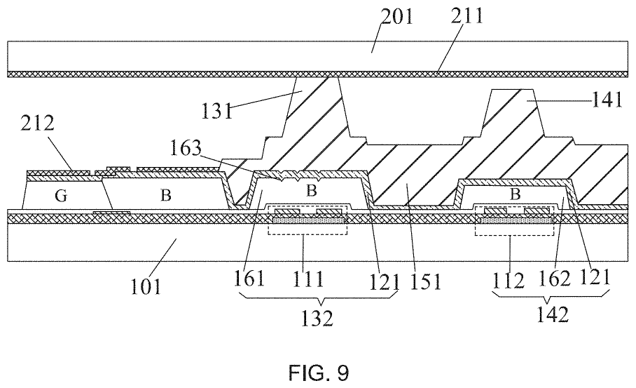

Please refer to FIG. 9, which is a structural diagram of a liquid crystal display panel according to a preferred embodiment of the present invention. The liquid crystal display panel of the present invention mainly includes an upper substrate 201, a lower substrate 101 and a padded black photo spacer disposed between the upper substrate 201 and the lower substrate 101; wherein the padded BPS includes a main photo spacer 131, an auxiliary photo spacer 141, a black matrix 151, a main photo spacer pad 132 and an auxiliary photo spacer pad 142; the main photo spacer pad 132 and the auxiliary photo spacer pad 142 are disposed on the lower substrate 101, and a height of the main photo spacer pad 132 is greater than a height of the auxiliary photo spacer pad 142; the black matrix 151 and the main photo spacer 131 are correspondingly disposed above the main photo spacer pad 132, and the black matrix 151 and the auxiliary photo spacer 141 are correspondingly disposed above the auxiliary photo spacer pad 142; the main photo spacer pad 132 includes a main photo spacer color resist pad 161, and a surface of the main photo spacer color resist pad 161 is provided with micro pits 163. The upper surface of the main photo spacer color resist pad 161 is provided with the micro pits 163 such that the upper surface of the main photo spacer color resist pad 161 is roughened, and the upper surface of the entire main photo spacer pad 142 is roughened. A transparent electrode 211 is further disposed between the upper substrate 201, the main photo spacer 131 and the auxiliary photo spacer 141; the pixel electrode 212 is provided on the color resist opposite to the transparent electrode 211. In the general liquid crystal display panel structure, a liquid crystal layer is interposed between the upper substrate 201 and the lower substrate 101, and a polarizing film is also attached to the outside, and details are not repeated herein.

In the liquid crystal display panel of the present invention, the main photo spacer color resist pad may comprise one or several layers of color resists, and one or several layers of color resists constitute a main photo spacer color resist pad; The main photo spacer pad includes a main photo spacer color resist pad, and may also include, but is not limited to, an inorganic planarization layer or an organic planarization layer, or may also include a thin film transistor. The key is that the main photo spacer pad is higher than the auxiliary photo spacer pad on the lower substrate. In the embodiment shown in FIG. 9, the main photo spacer color resist pad 161 includes a layer of blue color resist, and the main photo spacer pad 132 includes the main photo spacer color resist pad 161, and further includes a thin film transistor 111 and an inorganic passivation layer 121, the main photo spacer color resist pad 161 is disposed on the thin film transistor 111, and the inorganic passivation layer 121 covers the main photo spacer color resist pad 161.

The structure of the auxiliary photo spacer pad 142 may be similar to the main photo spacer pad 132. The key is that the main photo spacer pad 132 is higher than the auxiliary photo spacer pad 142 on the lower substrate 101. In this embodiment, the auxiliary photo spacer pad 142 includes the auxiliary photo spacer color resist pad 162, and further includes a thin film transistor 112 and an inorganic passivation layer 121, the auxiliary photo spacer color resist pad 162 is disposed on the thin film transistor 112, and the inorganic passivation layer 121 covers the auxiliary photo spacer color resist pad 162. The main photo spacer pad 132 and the auxiliary photo spacer pad 142 form a pad step on the lower substrate 101 such that the BPS layer including the main photo spacer 131, the auxiliary photo spacer 141 and the black matrix 151 possess various heights on the surface of the lower substrate 101. In this embodiment, for the technology architecture using the padded BPS, on the array substrate provided with the thin film transistor 111 and the thin film transistor 112, a color filter is simultaneously prepared, that is, a COA substrate is formed, and finally, an inorganic passivation layer 121 is deposited as a protective film; the main photo spacer pad 132 and the auxiliary photo spacer pad 142 form a pad step at positions where the main photo spacer 131 and the auxiliary photo spacer 141 are to be formed, wherein the main photo spacer color resist pad 161 and the auxiliary photo spacer color resist pad 162 included in the color filter are respectively used as portions of the main photo spacer pad 132 and the auxiliary photo spacer pad 142, and a single transmittance BPS material is coated on the main photo spacer 131 and the auxiliary photo spacer 141 and a full-tone mask is used in an exposure process to form the main photo spacer 131, the auxiliary photo spacer 141 and the black matrix 151.

The upper surface of the main photo spacer color resist pad 161 is provided with the micro pits 163. With the aforesaid photomask fabrication of the present invention, the special design of the light shielding pattern having the critical dimension can be introduced on the photomask. By using the overlay of the film thickness thinning zones, the upper surface roughness of the main photo spacer color resist pad 161 can be increased without substantially reducing the overall film thickness to increase the upper surface roughness of the main photo spacer pad 132. Accordingly, the level difference conversion rate can be increased when black photo spacer material is subsequently coated, and finally, the actual level difference between the main photo spacer 131 and the auxiliary photo spacer 141 can be adjusted to increase. The micro pits 163 in a small range on the upper surface of the main photo spacer color resist pad 161 are grooved or concaved and convexed in a lattice shape; an upper surface local roughness of the main photo spacer color resist pad 161 is set to be greater than 0.1 μm and less than 0.3 μm. A groove structure with a high circumference and a slightly depressed central portion is formed on a top of the main photo spacer 131, and the groove structure possesses a peak and trough value greater than 0.1 μm and less than 0.5 μm.

In conclusion, the photomask for fabricating the padded black photo spacer can increase a level difference conversion rate when black photo spacer material is subsequently coated, and finally, the actual level difference between the main photo spacer and the auxiliary photo spacer can be adjusted upward; the padded black photo spacer of the liquid crystal display panel possesses a larger level difference.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A photomask for fabricating a padded black photo spacer, provided with a pad pattern for forming a main photo spacer color resist pad, wherein the pad pattern includes a light transmissive region and a light shielding pattern having a critical dimension disposed in the light transmissive region; the light shielding pattern having the critical dimension is a regular pattern having a sufficiently small line dimension in a certain characteristic direction; the critical dimension is less than or equal to 5 μm.

2. The photomask according to claim 1, wherein a transmissive area proportion of the pad pattern is larger than or equal to 70%.

3. The photomask according to claim 1, wherein the light shielding pattern is a square shape, a triangular shape, a circular shape, an array of square shapes, a line shape, a mesh shape or a homocentric squares shape.

4. The photomask according to claim 1, wherein the critical dimension is less than or equal to 2 μm.

5. A liquid crystal display panel, including an upper substrate, a lower substrate and a padded black photo spacer disposed on the lower substrate; wherein the padded black photo spacer includes a photo spacer and a photo spacer pad disposed on the lower substrate and corresponding to the photo spacer, and a surface of the color resist layer in the photo spacer pad is provided with micro pits.

6. The liquid crystal display panel according to claim 5, wherein the padded black photo spacer includes a main photo spacer, an auxiliary photo spacer, a black matrix, a main photo spacer pad and an auxiliary photo spacer pad; the main photo spacer pad and the auxiliary photo spacer pad are disposed on the lower substrate, and a height of the main photo spacer pad is greater than a height of the auxiliary photo spacer pad; the black matrix and the main photo spacer are correspondingly disposed above the main photo spacer pad, and the black matrix and the auxiliary photo spacer are correspondingly disposed above the auxiliary photo spacer pad; the main photo spacer pad includes a main photo spacer color resist pad, and a surface of the main photo spacer color resist pad is provided with micro pits.

7. The liquid crystal display panel according to claim 5, wherein the micro pits are grooved or concaved and convexed in a lattice shape, and are located on the color resist layer near the surface of the photo spacer and possess a local roughness greater than 0.1 μm and less than 0.3 μm.

8. The liquid crystal display panel according to claim 5, wherein a groove structure with a high circumference and a slightly depressed central portion is formed on a top of the photo spacer, and the groove structure possesses a peak and trough value greater than 0.1 μm and less than 0.5 μm.

9. The liquid crystal display panel according to claim 5, wherein the color resist layer in the photo spacer pad forms the photo spacer color resist pad, and the photo spacer color resist pad includes one or more layers of color resists.

10. The liquid crystal display panel according to claim 5, wherein the photo spacer pad further includes an inorganic planarization layer or an organic planarization layer, or includes a thin film transistor.
